(19) United States
(12) Patent Application Publication
(10) Pub. No.: US 2009/0039527 A1
(43) Pub. Date: Feb. 12, 2009

(54) Sensor-type package and method for fabricating the same

(75) Inventors: Chang-Yueh Chan, Taichung (TW); Chien-Ping Huang, Taichung (TW); Tse-Wen Chang, Taichung (TW); Chin-Huang Chang, Taichung (TW); Chih-Ming Huang, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 12/221,725

(22) Filed: Aug. 6, 2008

(30) Foreign Application Priority Data
Aug. 6, 2007 (TW) 096128799

(51) Int. Cl. H01L 23/52; H01L 21/00

(52) U.S. Cl. 257/777; 438/109; 257/E23.141; 257/E21.001

(57) ABSTRACT

A sensor-type package and a method for fabricating the same are provided. A wafer having a plurality of semiconductor chips is provided, wherein a plurality of holes are formed on a first surface of each of the semiconductor chips, and a plurality of metallic pillars formed in the holes and a plurality of bond pads connected to the metallic pillars form through silicon vias (TSVs). A groove is formed on a second surface of each of the semiconductor chips to expose the metallic pillars. A plurality of sensor chips having TSVs are stacked in the grooves of the semiconductor chips and electrically connected to the exposed metallic pillars. A transparent cover is mounted onto the second surfaces of the semiconductor chips to cover the grooves. A plurality of conductive components are implanted on the bond pads of the semiconductor chips. The wafer is cut along borders among the semiconductor chips.

### BACKGROUND OF THE INVENTION

1. Field of the Invention

The present invention relates to semiconductor packages and methods for fabricating the same, and more particularly, to a sensor-type package and a method for fabricating the sensor-type package.

2. Description of the Prior Art

Conventional image sensor packages, such as the ones disclosed in U.S. Pat. Nos. 6,060,340, 6,262,479 and 6,590,269, prepare a dam structure on a chip carrier, before receiving and wire-bonding a sensor chip to the space defined by the dam structure on the chip carrier and attaching a transparent glass on the dam structure to cover the space. However, such sensor-type packages are limited by the needs to have at least sufficient space for disposing the dam structure on the chip carrier. At the same time, the sensor-type packages are required to be electrically connected to the chip carrier via bonding wires. As such, sizes of the sensor-type packages are limited by dam structures and distributions of bonding wires, such that they cannot be further reduced to improve electrical properties of the sensor-type packages.

Referring to FIG. 1, U.S. Pat. No. 6,995,462 discloses a sensor-type package without using a dam structure or electrically connecting a sensor chip to a sensor carrier via bonding wires. The invention mainly provides a sensor chip 12 having an active surface 121 and a non-active surface 122 opposite each other. A sensing area 123 and a plurality of bond pads 124 are situated and disposed, respectively, on the active surface 121. A transparent cover 15 is mounted onto an adhesive layer 14 on the active face 121. Metallic pillars 126 are formed in the sensor chip 12 by a through silicon via (TSV) technique, and the bond pads 124 on the active surface 121 of the sensor chip 12 are electrically connected to solder bumps 125 on the non-active surface 122 of the sensor chip 12 via the metallic pillars 126, so that the sensor chip 12 is mounted onto and electrically connected to the chip carrier (such as a substrate) via the solder bumps 125.

The aforesaid sensor-type package requires that the sensor chip be electrically connected to the chip carrier, which is used to electrically connect the chip to an external device. This is a package at package-level, which is not only bulky but also expensive. Moreover, control units such as digital signal processors (DSP) cannot be integrated in the sensor-type package. Therefore, the sensor-type package cannot meet the demands of lightness, thinness, shortness, smallness and high degrees of integration from the industry.

Furthermore, referring to FIGS. 2A through 2F, U.S. Pat. Nos. 5,270,261 and 5,202,754 disclose using the TSV technique to provide a plurality semiconductor chips stacked and interconnected to form a multi-chip module (MCM), which mainly provides a first wafer 21a having a first surface 211 and a second surface 212 opposite each other. The first wafer 21a includes a plurality of first chips 21, wherein a plurality of holes 210 are formed over the first surface 211 and a plurality of metallic pillars 23 are formed in the holes 210 to form a TSV. The exposed ends of the metallic pillars 23 form bond pads 231 to adhere the first surface 211 of the first wafer 21a to a support 251 (such as glass) through an adhesive layer 241, so as to use the support 251 to provide supporting strength required for the process (as shown in FIG. 2A); applying a grinding process to laminate the second surface 212 of the first wafer 21a, so as to expose the metallic pillars 23 (as shown in FIG. 2B); forming a plurality of bond pads 232 over the metallic pillars 23 exposed from the second surface 212, so that the second wafer 22a having a plurality of second chips 22 can be perpendicularly mounted onto and electrically connected to the second surface 212 of the first wafer 21a via the metallic pillars 26 of the TSV (as shown in FIG. 2C); repeating the aforesaid process to laminate the second wafer 22a having a plurality of second chips 22, so as to expose the metallic pillars 26 of the TSV and form the bond pads 236 on the exposed metallic pillars 26 (as shown in FIG. 2D); subsequently providing the first chips 21 and the second chips 22 to be electrically connected to the external device, the step requires implanting a plurality of solder balls on the first surface of the first chips and adhering the first wafer 21a and the second wafer 22a to another support 252 (such as glass) by an adhesive layer 242, to expose the first surface 211 of the first wafer 21a (as shown in FIG. 2E); implanting a plurality of solder balls 27 on the bond pads 231 on the first surface 211 of the first wafer 21a (as shown in FIG. 2F); cutting the stacked first wafer 21a and the second wafer 21b to form a plurality of perpendicularly stacked first chips 21 and second chips 22, which are then electrically connected to a substrate 28 via the solder balls 27 to form a MCM semiconductor package (as shown in FIG. 2G).

However, in the aforesaid process, the additional use of a plurality of supports 251 and 252, along with the adhesion of the first wafer 21a and the second wafer 22a for multiple times on the supports 251 and 252, not only increase production costs, but also raise complexity of processes. Furthermore, if the adhesive layers 241 and 242 are high-molecular materials such as epoxy resins, sputtering and stripping processes typically used to form the bond pads 231 and 236 are extremely likely to cause contaminations that leading to lowered productions.

Accordingly, the prior arts, which use the TSV technique to provide a plurality of semiconductor chips stacked and interconnected to form a MCM, cannot be effectively applied to sensor-type packages. It is important to develop a light, thin, short, small and highly integrated wafer-level sensor-type package and a method for fabrication the same, with low production costs and process complexity.

### SUMMARY OF THE INVENTION

In view of the aforesaid drawbacks, it is therefore an objective of this invention to provide a light, thin, short and small wafer-level sensor-type package and a method for fabricating the same.

It is another objective of this invention to provide an easily fabricated, low cost sensor-type package and a method for fabricating the same.

It is still another objective of this invention to provide a highly integrated sensor-type package and a method for fabricating the same.

It is yet another objective of this invention to provide a sensor-sensor package, whereby control units can be integrated, and a method for fabricating the same.

It is yet another objective of this invention to provide a sensor-type package, whereby contamination due to uses of high-molecular adhesive layers is avoided or uses supports, and a method for fabricating the same.

In accordance with the foregoing and other objectives, the invention discloses a method for fabricating a sensor-type package, including: providing a wafer comprising a plurality of semiconductor chips, the wafer and the semiconductor chips each having a first surface and a second surface opposite to the first surface, wherein a plurality of holes are formed on the first surface of each of the semiconductor chips, for allowing a plurality of metallic pillars to be formed in the holes and a plurality of bond pads to be formed on the first surface of each of the semiconductor chips and connected to the metallic pillars so as to form a plurality of through silicon vias (TSVs); forming a groove on the second surface of each of the semiconductor chips to expose partly the metallic pillars of the TSVs by the groove; stacking a plurality of sensor chips, which are formed with TSVs therein, in the grooves of the semiconductor chips, and electrically connecting the stacked sensor chips to the metallic pillars exposed by the grooves of the semiconductor chips; and mounting a transparent cover onto the second surfaces of the semiconductor chips, for covering the grooves.

The method further includes disposing a plurality of conductive components on the bond pads formed on the first surface of the semiconductor chips; and cutting the wafer along borders between the semiconductor chips.

Each of the sensor chips has an active surface and a non-active surface opposite to the active surface. A sensing area is formed on each of the sensor chips, and a TSV is formed in each of the sensor chips. The sensor chips are mounted onto the grooves of the semiconductor chips via their non-active surfaces, so that the sensing areas are exposed by the grooves and TSV of the sensor chips is electrically connected to the metallic pillars of the TSV, which are exposed by the grooves, of the semiconductor chips. The depths of the grooves are greater than the heights of sensor chips.

Moreover, the grooves can be filled (but not the sensing areas) with an insulative material to effectively fix the sensor chips in the grooves; a plurality of passive components can be further mounted in the grooves to enhance overall electrical quality of the sensor-type package. Furthermore, a lens mount can be disposed on one side of the sensor-type package corresponding to the transparent cover.

By the aforesaid process, the invention further discloses a sensor-type package, including: a semiconductor chip having a first surface and a second surface opposite to the first surface, wherein a plurality of holes are formed on the first surface of the semiconductor chip, a plurality of through silicon vias (TSVs) are formed in the semiconductor chip and comprise a plurality of metallic pillars formed in the holes and a plurality of bond pads formed on the first surface of the semiconductor chip and connected to the metallic pillars, and a groove is formed on the second surface of the semiconductor chip, with the metallic pillars of the TSVs being partly exposed by the groove; a sensor chip having an active surface and a non-active surface opposite to the active surface, wherein the active surface is formed with a sensing area thereon, and a plurality of TSVs are formed in the sensor chip, the sensor chip being mounted via the non-active surface thereof in the groove of the semiconductor chip and electrically connected to the metallic pillars of the semiconductor chip exposed by the groove, with the sensing area of the sensor chip being exposed to the groove; and a transparent cover mounted onto the second surface of the semiconductor chip and covering the groove.

The stacked multi-chip structure further includes an insulative material filled in the groove of the semiconductor chip (but not the sensing areas of the sensor chip); and a plurality of passive components mounted in the groove and electrically connected to the metallic pillars, which are exposed by the groove, of the TSV of the semiconductor chip.

Accordingly, the sensor-type package and the method for fabricating the same, of the invention, mainly includes: providing a wafer comprising a plurality of semiconductor chips, the wafer and the semiconductor chips each having a first surface and a second surface opposite to the first surface, wherein a plurality of holes are formed on the first surface of each of the semiconductor chips, for allowing a plurality of metallic pillars to be formed in the holes and a plurality of bond pads to be formed on the first surface of each of the semiconductor chips and connected to the metallic pillars so as to form a plurality of through silicon vias (TSVs); forming a groove on the second surface of each of the semiconductor chips to expose partly the metallic pillars of the TSVs by the groove; stacking a plurality of sensor chips, which are formed with TSVs therein, in the grooves of the semiconductor chips, and electrically connecting the stacked sensor chips to the metallic pillars exposed by the grooves of the semiconductor chips; and mounting a transparent cover onto the second surfaces of the semiconductor chips, for covering the grooves; mounting a plurality of conductive components on the bond pads on the first surface of the semiconductor chips; and cutting the wafer along borders among the semiconductor chips.

By doing so, a wafer-level process is completed, such that light, thin, short, small and highly integrated sensor-type packages are formed. The aforesaid wafer-level process can provide a light, thin, short and small sensor-type package. Additionally, sensor chips having TSV are stacked and electrically connected to DSP control units disposed with TSV to provide a highly integrated sensor-type package. At the same time, the invention uses the unlaminated wafer (having a plurality of semiconductor chips) as supporting carriers in the processes, so as to avoid the problems of complexity of processes, high costs and possible contamination caused by applying the TSV technique, as used in the prior arts, to perpendicularly stack a plurality of chips and use supports and adhesive layers for multiple times to mount the chips on the chip carriers.

### BRIEF DESCRIPTION OF THE DRAWINGS

FIG. 1 is a schematic diagram of a sensor-type package disclosed in the U.S. Pat. No. 6,995,462;

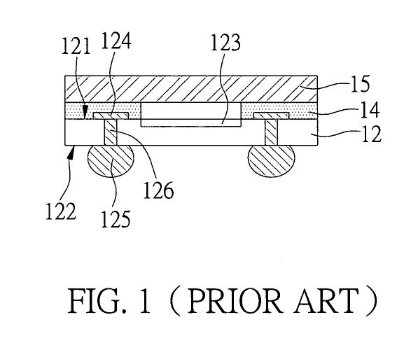

FIGS. 2A to 2G are schematic diagrams of a plurality of semiconductor chips perpendicularly stacked by the TSV technique, as disclosed in the U.S. Pat. Nos. 5,270,261 and 5,202,754;

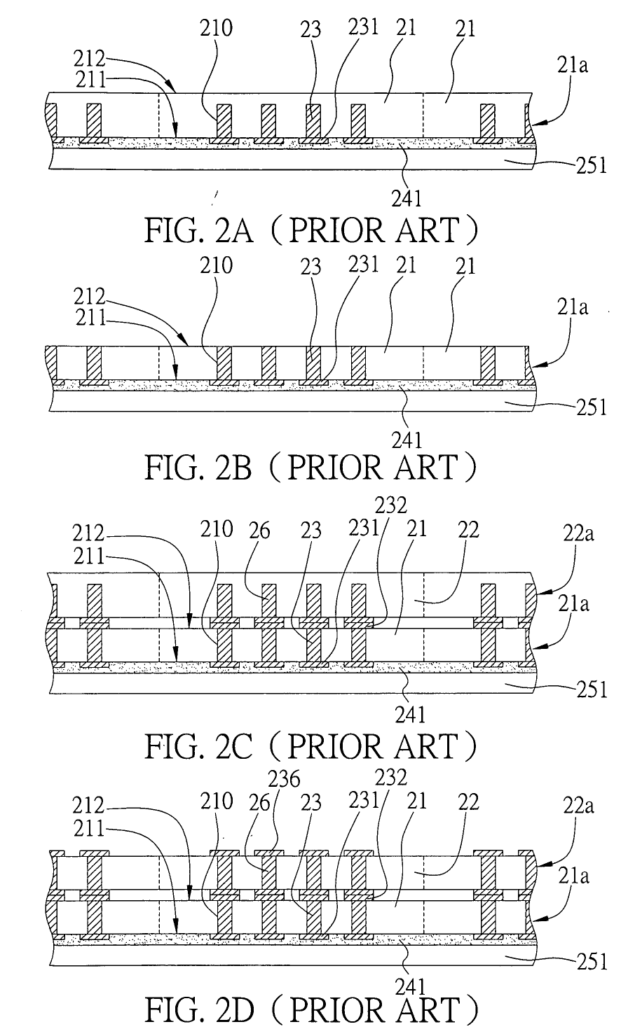

FIGS. 3A to 3F are schematic diagrams of a sensor-type package and a method for fabricating the same according to a first embodiment of the invention;

FIG. 4 is a schematic diagram of a sensor-type package and a method for fabricating the same according to a second embodiment of the invention;

FIG. 5 is a schematic diagram of a sensor-type package and a method for fabricating the same according to a third embodiment of the invention; and

FIG. 6 is a schematic diagram of a sensor-type package and a method for fabricating the same according to a fourth embodiment of the invention.

### DETAILED DESCRIPTION OF THE PREFERRED EMBODIMENTS

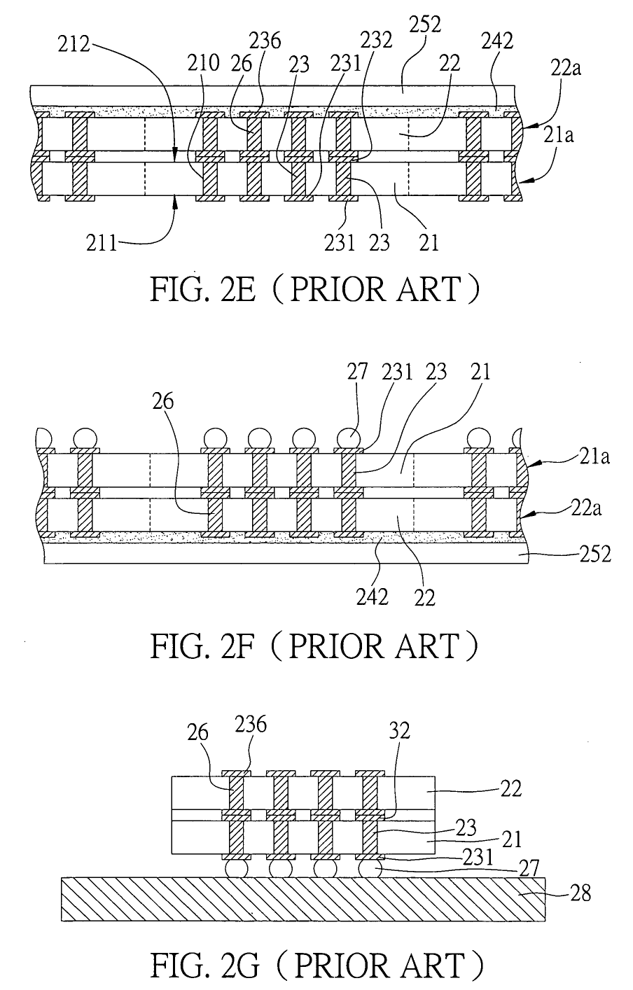

Illustrative embodiments of a sensor-type package and a method for fabricating the same provided in the present invention are described as follows with reference to FIGS. 3 to 6. It should be understood that the drawings are simplified schematic diagrams only showing the components relevant to the present invention, and the layout of components could be more complicated in practical implementation.

### First Embodiment

Referring to FIGS. 3A through 3F, FIGS. 3A through 3F are schematic diagrams of a sensor-type package and a method for fabricating the same according to the first embodiment of the invention.

As shown in FIG. 3A, a wafer 31a containing a plurality of semiconductor chips 31a (such as DSP) are provided. The wafer 31a and each of the semiconductor chips 31 have a first surface 311 and a second surface 312 opposite to the first surface 311, wherein a plurality of holes 310 are formed over the first surface 311 of the semiconductor chips 31, to form a plurality of metallic pillars 33 and bond pads 331, respectively, in and on the holes 310 to form a TSV.

A silicon dioxide or silicon nitride insulative layer 33″ is disposed between the holes 310 and the metallic pillars 33 of the TSV, and a nickel barrier layer 33′ is disposed between the insulative layer 33″ and the metallic pillars 33. Materials of the metallic pillars can be, for example, one of copper, gold, aluminum, etc.

As shown in FIG. 3B, the second surface 312 of the semiconductor chips 31 is etched to form at least a groove 3120 in each by deep reactive ion etching (DRIE), and the metallic pillars 33 of the TSV are exposed by the bottom of the grooves 3120, wherein the metallic pillars 33 can protrude outwardly.

As shown in FIG. 3C, sensor chips 32 are stacked on the semiconductor chips 31 and contained in the grooves 3120. The sensor chips 32 are electrically connected to the metallic pillars 33 protruding outwardly from the grooves 3120.

Each of the sensor chips 32 has an active surface 321 and a non-active surface 322 opposite each other. A sensing area 323 is formed on the active surface 321, and a plurality of bond pads 324 are disposed on the active surface 321. A plurality of conductive bumps 325 are disposed on the non-active surface 322. Metallic pillars 326, which are electrically connected to the bond pads 324 and the conductive bumps 325, are formed in the sensor chip 32 to form a TSV.

The sensor chips 32 are mounted in the grooves 3120 of the semiconductor chips 31 via their non-active surfaces, so that the conductive bumps 325 are electrically connected to the metallic pillars 33, which are exposed by the grooves 3120, of the TSV of the semiconductor chips 31 and the sensing areas 323 are exposed by the grooves 3120, wherein the depths of the grooves 3120 are greater than the heights of sensor chips 32.

As shown in FIG. 3D, a transparent cover 35 covering the grooves 3120 is mounted onto the second surface 312 of the semiconductor chips 31. An example of the transparent cover 35 is glass.

As shown in FIGS. 3E and 3F, a plurality of conductive components 37 can be further mounted on the bond pads 331 on the first surface 311 of the semiconductor chips 31, and the wafer 31a can be cut along borders among the semiconductor chips 31.

By the aforesaid process, the invention further discloses a sensor-type package, including: a semiconductor chip 31 having a first surface 311 and a second surface 312 opposite to the first surface 311, wherein a plurality of holes 310 formed on the first surface 311, and a plurality of metallic pillars 33 in the holes and bond pads 331 are formed on the first surface 311 to form a TSV; a groove 3120 formed on the second surface 312 to expose partly the metallic pillars 33 of the TSV; a sensor chip 32 having an active surface 321 and a non-active surface 322 opposite to the active surface 321, wherein a sensing area 323 situated on the active surface 321, a TSV is formed in the sensor chip 32, and the sensor chip 32 is mounted in the groove 3120 of the semiconductor chip 31 via its non-active surface 322, and electrically connected to the metallic pillars 33, exposed from the groove 3120, of the TSV of the semiconductor chip 31, so that the sensing area 323 is also exposed by the groove 3120; and a transparent cover 35 mounted onto the second surface 312 of the semiconductor chip 31 to cover the groove 3120.

Accordingly, the sensor-type package and the method for fabricating the same, of the invention, includes providing a wafer comprising a plurality of semiconductor chips, the wafer and the semiconductor chips each having a first surface and a second surface opposite to the first surface, wherein a plurality of holes are formed on the first surface of each of the semiconductor chips, for allowing a plurality of metallic pillars to be formed in the holes and a plurality of bond pads to be formed on the first surface of each of the semiconductor chips and connected to the metallic pillars so as to form a plurality of through silicon vias (TSVs); forming a groove on the second surface of each of the semiconductor chips to expose partly the metallic pillars of the TSVs by the groove; stacking a plurality of sensor chips, which are formed with TSVs therein, in the grooves of the semiconductor chips, and electrically connecting the stacked sensor chips to the metallic pillars exposed by the grooves of the semiconductor chips; and mounting a transparent cover onto the second surfaces of the semiconductor chips, for covering the grooves.; and cutting the wafer along borders among the semiconductor chips. The aforesaid wafer-level process can provide a light, thin, short 10 and small sensor-type package. Additionally, sensor chips having TSV are stacked and electrically connected to DSP control units disposed with TSV to provide a sensor-type package with high degrees of integration. At the same time, the invention uses the unlaminated wafer (having a plurality of semiconductor chips) as supporting carriers in the processes, so as to avoid the problems of complexity of processes, high costs and possible contamination caused by applying the TSV technique, as used in the prior arts, to perpendicularly stack a plurality of chips and use supports and adhesive layers for multiple times to mount the chips on the chip carriers.

### Second Embodiment

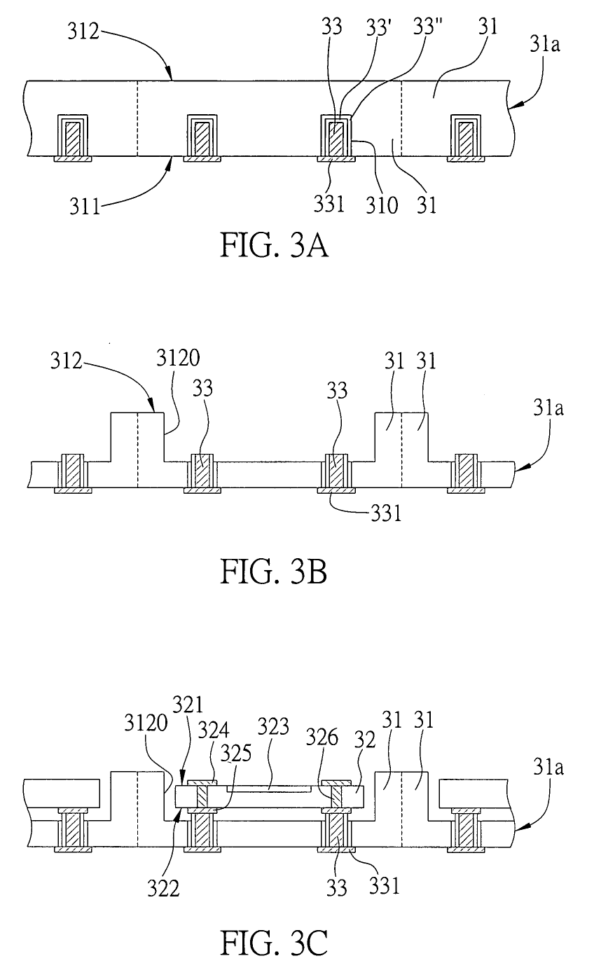

Referring to FIG. 4, FIG. 4 is a schematic diagram of a sensor-type package and a method for fabricating the same according to the second embodiment of the invention. For simplicity, identical or similar components are represented by the same symbol.

The sensor-type package and the method for fabricating the same, of the embodiment, is substantially the same as the ones described in the first embodiment. The major difference is that the insulative material 34 is filled in the groove 3120 (but not the sensing area 323 of the sensor chip 32) on the second surface 312 of each of the semiconductor chips 31 of the wafer 31a, so as to effectively fix the sensor chip 32 in the groove 3120.

### Third Embodiment

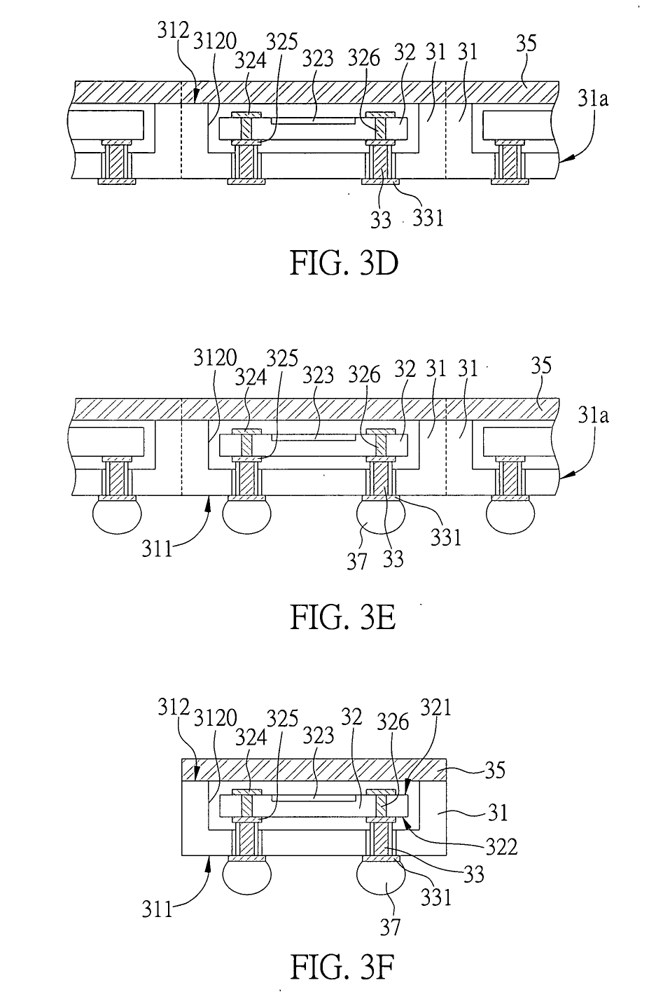

Referring to FIG. 5, FIG. 5 is a schematic diagram of a sensor-type package and a method for fabricating the same according to the third embodiment of the invention. For simplicity, identical or similar components are represented by the same symbol.

The sensor-type package and a method for fabricating the same, of the embodiment, is substantially the same as the ones described in the first embodiment. The major difference is that the passive components 38 can be further mounted onto and electrically connected to the groove 3120 on the second surface 312 of the semiconductor chips 31, so as to enhance the electrical property of the sensor-type package.

### Fourth Embodiment

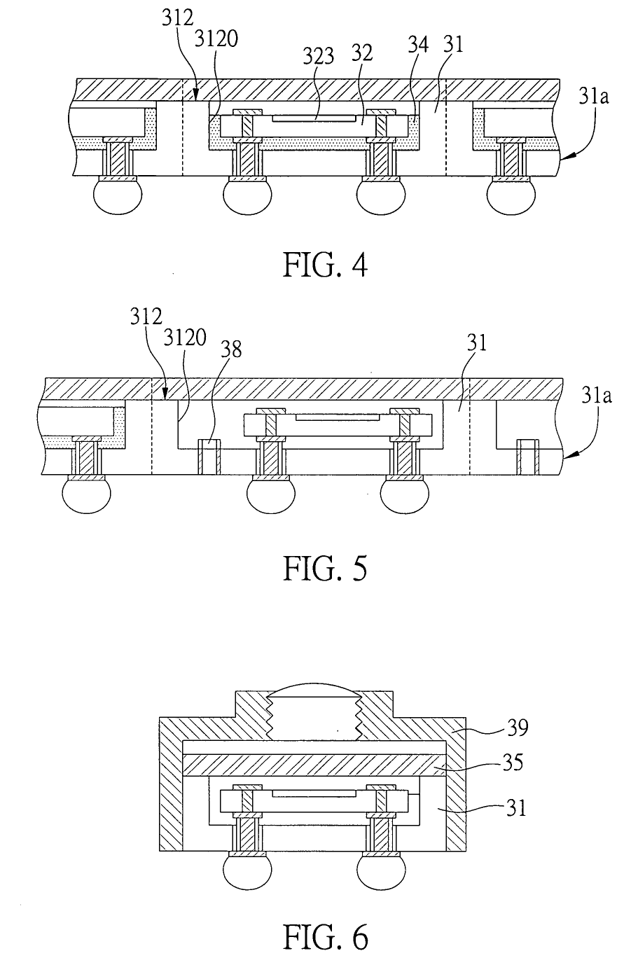

Referring to FIG. 6, FIG. 6 is a schematic diagram of a sensor-type package and a method for fabricating the same according to the fourth embodiment of the invention. For simplicity, identical or similar components are represented by the same symbol.

The sensor-type package and the method for fabricating the same, of the embodiment, is substantially the same as the one described in the first embodiment. The major difference is that a lens mount 39 is disposed on one side of the semiconductor chip 31 corresponding to the transparent cover 35, so as to enhance light absorbance.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

What is claimed is:

1. A method for fabricating a sensor-type package, comprising:
providing a wafer comprising a plurality of semiconductor chips, the wafer and the semiconductor chips each having a first surface and a second surface opposite to the first surface, wherein a plurality of holes are formed on the first surface of each of the semiconductor chips, for allowing a plurality of metallic pillars to be formed in the holes and a plurality of bond pads to be formed on the first surface of each of the semiconductor chips and connected to the metallic pillars so as to form a plurality of through silicon vias (TSVs);
forming a groove on the second surface of each of the semiconductor chips to expose partly the metallic pillars of the TSVs by the groove;
stacking a plurality of sensor chips, which are formed with TSVs therein, in the grooves of the semiconductor chips, and electrically connecting the stacked sensor chips to the metallic pillars exposed by the grooves of the semiconductor chips; and
mounting a transparent cover onto the second surfaces of the semiconductor chips, for covering the grooves.

2. The method of claim 1, further comprising disposing an insulative layer between the holes and the metallic pillars, and disposing a barrier layer between the insulative layer and the metallic pillars.

3. The method of claim 2, wherein the insulative layer is made of one of silicon dioxide and silicon nitride, the barrier layer is made of nickel, and the metallic pillars are made of one of copper, gold and aluminum.

4. The method of claim 1, wherein the grooves of the semiconductor chips are formed by deep reactive ion etching (DRIE).

5. The method of claim 1, wherein each of the sensors chips comprises an active surface, a non-active surface opposite to the active surface, a sensing area and a plurality of bond pads formed on the active surface, a plurality of conductive bumps mounted on the non-active surface, and a plurality of metallic pillars formed in the sensor chip and electrically connecting the bond pads on the active surface to the conductive bumps on the non-active surface so as to form the TSVs.

6. The method of claim 1, wherein the grooves of the semiconductor chips have a depth greater than a height of the sensor chips.

7. The method of claim 1, further comprising:
implanting a plurality of conductive components on the bond pads formed on the first surfaces of the semiconductor chips; and
cutting the wafer along borders among the semiconductor chips to form a plurality of sensor-type packages.

8. The method of claim 5, wherein the grooves of the semiconductor chips are filled with an insulative material, with the sensing areas of the sensor chips being exposed from the insulative material.

9. The method of claim 1, further comprising mounting a plurality of passive components in the grooves of the semiconductor chips and electrically connecting the passive components to the semiconductor chips.

10. The method of claim 1, further comprising disposing a lens mount on a side of each of the semiconductor chips where the transparent cover is mounted.

11. A sensor-type package, comprising:
a semiconductor chip having a first surface and a second surface opposite to the first surface, wherein a plurality of holes are formed on the first surface of the semiconductor chip, a plurality of through silicon vias (TSVs) are formed in the semiconductor chip and comprise a plurality of metallic pillars formed in the holes and a plurality of bond pads formed on the first surface of the semiconductor chip and connected to the metallic pillars, and a groove is formed on the second surface of the semiconductor chip, with the metallic pillars of the TSVs being partly exposed by the groove;
a sensor chip having an active surface and a non-active surface opposite to the active surface, wherein the active surface is formed with a sensing area thereon, and a plurality of TSVs are formed in the sensor chip, the sensor chip being mounted via the non-active surface thereof in the groove of the semiconductor chip and electrically connected to the metallic pillars of the semiconductor chip exposed by the groove, with the sensing area of the sensor chip being exposed to the groove; and
a transparent cover mounted onto the second surface of the semiconductor chip and covering the groove.

12. The sensor-type package of claim 11, further comprising an insulative layer disposed between the holes and the metallic pillars, and a barrier layer disposed between the insulative layer and the metallic pillars.

13. The sensor-type package of claim 12, wherein the insulative layer is made of one of silicon dioxide and silicon nitride, the barrier layer is made of nickel, and the metallic pillars are made of one of copper, gold and aluminum.

14. The sensor-type package of claim 11, wherein the groove is formed by deep reactive ion etching (DRIE).

15. The sensor-type package of claim 11, wherein the sensor chip further comprises a plurality of bond pads formed on the active surface, a plurality of conductive bumps disposed on the non-active surface, and a plurality of metallic pillars formed in the sensor chip, for electrically connecting the bond pads on the active surface to the conductive bumps on the non-active surface so as to form the TSVs.

16. The sensor-type package of claim 11, wherein a depth of the groove is greater than a height of the sensor chip.

17. The sensor-type package of claim 11, further comprising a plurality of conductive components disposed on the bond pads formed on the first surface of the semiconductor chip.

18. The sensor-type package of claim 11, wherein the groove is filled with an insulative material, with the sensing area of the sensor chip being exposed from the insulative material.

19. The sensor-type package of claim 11, further comprising a plurality of passive components mounted in the groove and electrically connected to the semiconductor chip.

20. The sensor-type package of claim 11, further comprising a lens mount disposed on a side of the semiconductor chip where the transparent cover is mounted.
